(19) United States
(12) Patent Application Publication
(10) Pub. No.: US 2026/0028905 A1
(43) Pub. Date: Jan. 29, 2026

(54) METHOD AND SYSTEM FOR OPTIMIZING THE PLANNING OF HYDROCARBON FACILITIES

(71) Applicant: SAUDI ARABIAN OIL COMPANY, Dhahran (SA)

(72) Inventor: Ali Redha H. ALNASSER, Dhahran (SA)

(73) Assignee: SAUDI ARABIAN OIL COMPANY, Dhahran (SA)

(21) Appl. No.: 18/784,530

(22) Filed: Jul. 25, 2024

(51) Int. Cl. E21B 43/30; G06F 30/20

(52) U.S. Cl. CPC E21B 43/30; G06F 30/20; E21B 2200/20

(57) ABSTRACT

System and methods are disclosed relating to field development planning in the petroleum industry, and more specifically, to optimizing the planning of hydrocarbon facilities by receiving parameters as input such as well locations and tie-in locations, sorting the parameters into different arrays, generating future wells, constructing distance matrices, filtering out connections that do not abide by constraints, picking optimal connections, updating arrays, and reiterating to smooth out inherent uncertainties.

### FIELD OF DISCLOSURE

This disclosure relates generally to field development planning in the petroleum industry, and more specifically, to optimizing the planning of hydrocarbon facilities.

### BACKGROUND OF THE DISCLOSURE

In the petroleum industry, the planning and placement of hydrocarbon facilities is crucial to the efficiency of gas field development. There are infinite combinations of often conflicting considerations, including distances to existing wells, existing manifolds, other existing facilities, pipelines, or field assets, the subsurface reservoirs' target of different fluids compositions and its tie-in locations and connection alignment, etc. Planning and developing new hydrocarbon facilities or their corresponding optimal well locations is costly and highly challenging. The complexity of reservoirs and existing obstructions in the gas field cause optimal locations to be difficult to quantify. Conditions further vary drastically from gas field to gas field. The complex subsurface conditions are often captured through numerical models that use data containing high uncertainties. The uncertainty in the data as well as potential biases and human error amplify the difficulty of the endeavor of planning hydrocarbon facilities through both automated and manual means. Existing generic workflows fail to utilize multiple reservoir simulation models to reduce the influence of the inherited uncertainties, and more pertinently, fail to integrate the complexities of the subsurface reservoir uncertainties as input into their workflows.

In an environment where increasingly difficult hydrocarbon assets of higher value need to be planned and developed in increasingly complex gas fields with fewer resources, there is a need for an automatic and comprehensive optimization tool for the placement of such facilities that integrates the uncertainty inherited from the complex reservoirs it aims to develop around.

### SUMMARY OF THE DISCLOSURE

Various details of the present disclosure are hereinafter summarized to provide a basic understanding. This summary is not an extensive overview of the disclosure and is neither intended to identify certain elements of the disclosure nor to delineate the scope thereof. Rather, the primary purpose of this summary is to present some concepts of the disclosure in a simplified form prior to the more detailed description that is presented hereinafter.

According to an embodiment consistent with the present disclosure, a hydrocarbon facility planning optimization system includes a hydrocarbon facility planner configured to receive input data, wherein the hydrocarbon facility planner includes a sorter operable to sort the input data into different arrays; a future well generator operable to generate future well locations in at least one area of interest; a distance calculator operable to create distance matrices from the sorted input data and future well locations to determine a plurality of connections; a connection filter operable to filter out invalid connections; a prioritizer operable to prioritize optimal well scenarios from the plurality of connections; and an updater operable to update the arrays to include the optimal well scenarios.

According to another embodiment, a method for optimizing the planning of hydrocarbon facilities includes receiving a set of parameters as input, including well locations and tie-ins locations, and executing an optimization workflow upon the set of parameters wherein the optimization workflow includes sorting the parameters into different arrays including a future wells array, generating future well locations within at least one area of interest, calculating distance matrices between wells and tie-ins to determine a plurality of connections, filtering out connections that do not abide by the set of parameters, prioritizing optimal well scenarios, and updating the arrays to include the optimal well scenarios.

In a further embodiment, a computer-readable storage medium containing instructions for optimizing the planning of hydrocarbon facilities is disclosed, wherein the instructions, when executed by a processor, cause the processor to perform operations including receiving a set of parameters as input, including well locations and tie-ins locations, and executing an optimization workflow upon the set of parameters wherein the optimization workflow includes: sorting the parameters into different arrays including a future wells array, generating future well locations within at least one area of interest, calculating distance matrices between wells and tie-ins to determine a plurality of connections, filtering out connections that do not abide by the set of parameters, prioritizing optimal well scenarios, and updating the arrays to include the optimal well scenarios.

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE DRAWINGS

FIGS. 1A and 1B are flowchart diagrams depicting an example of a method for optimizing the planning of hydrocarbon facilities.

FIG. 1C is a flowchart diagram depicting an example of a method for prioritization according to an embodiment consistent with the present disclosure.

FIG. 2 is a diagram depicting an example of a tabulation of a distance comparison scenario and alternative scenarios, according to at least one embodiment consistent with the present disclosure.

FIG. 3 is a diagram representing an example of a statistical analysis of an area of total pipeline length utilizing a manifold at a certain location which may be produced by an embodiment consistent with the present disclosure.

FIG. 4 is a diagram representing an example of a map illustration of a solved problem by the workflow.

FIG. 5 is a diagram representing an example of a wholistic flow diagram of the method for optimizing the planning of hydrocarbon facilities according to at least one embodiment.

FIGS. 6A and 6B are block diagrams depicting examples of a hydrocarbon facility planning optimization system according to some embodiments.

FIG. 7 depicts an example computing environment that can be used to perform methods according to an aspect of the present disclosure.

FIG. 8 depicts a cloud computing environment that can be used to perform one or more actions according to an aspect of the present disclosure.

### DETAILED DESCRIPTION

Embodiments of the present disclosure will now be described in detail with reference to the accompanying Figures. Like elements in the various figures may be denoted by like reference numerals for consistency. Further, in the following detailed description of embodiments of the present disclosure, numerous specific details are set forth in order to provide a more thorough understanding of the claimed subject matter. However, it will be apparent to one of ordinary skill in the art that the embodiments disclosed herein may be practiced without these specific details. In other instances, well-known features have not been described in detail to avoid unnecessarily complicating the description. Additionally, it will be apparent to one of ordinary skill in the art that the scale of the elements presented in the accompanying Figures may vary without departing from the scope of the present disclosure.

Embodiments of the present disclosure relate to field development planning in the petroleum industry, and more specifically, to optimizing the planning of hydrocarbon facilities.

The methods and systems disclosed herein offer a highly specialized solution tailored specifically to the planning of gas facilities. Existing generic workflows fail to integrate the complexities of the subsurface reservoirs' uncertainty as input to the process and workflow as areas of uncertainty. Placement of gas facilities and correlated wells will depend on the results of each successive well as new data to be integrated across existing reservoir characterization models. This will allow for a better understanding of the extent of the reservoir development by accounting for and minimizing the uncertainty. The uncertainties are critical in determining optimal facility placement, especially in heterogeneous reservoirs. Further, the disclosed methods and systems account for any constraints maintained by the user or other surface facilities, because the facilities network in gas fields can be relatively straight forward due to numerous factors affecting their orientation, such as high pressure areas. This allows for the ability to dial or generate various statistics to guide a user to an optimal gas facility placement result. The disclosed methods and systems accurately predict the need for new facilities as well as their optimal placements.

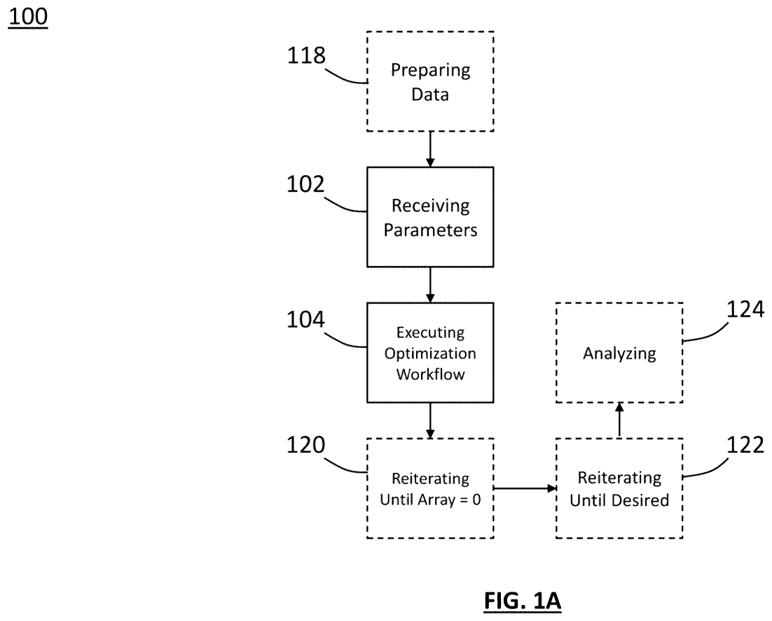

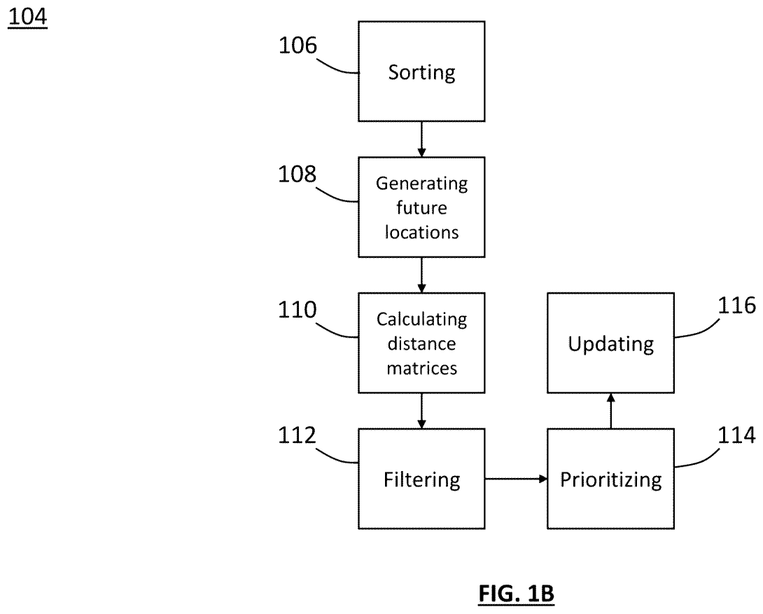

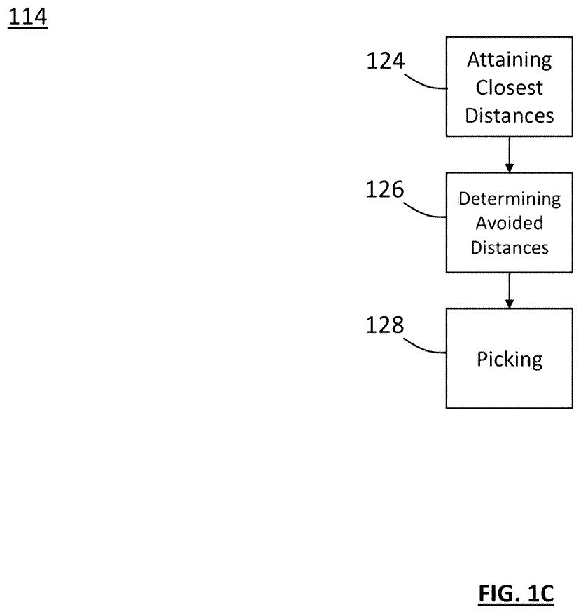

In view of the foregoing structural and functional features described above, an example(s) method will be better appreciated with reference to FIGS. 1A-C. While, for purposes of simplicity of explanation, the example method(s) of FIGS. 1A-C is shown and described as executing serially, it is to be understood and appreciated that the present examples are not limited by the illustrated order, as some actions could in other examples occur in different orders, multiple times and/or concurrently from that shown and described herein. Moreover, it is not necessary that all described actions be performed to implement the method(s).

FIGS. 1A and 1B are flowchart diagrams depicting an example of a method for optimizing the planning of hydrocarbon facilities. Method 100 comprises receiving a set of parameters as input at step 102, including well locations and tie-ins locations, and executing an optimization workflow upon the set of parameters at step 104 wherein the optimization workflow comprises: sorting the parameters into different arrays including a future wells array at step 106, generating future well locations within at least one area of interest at step 108, calculating distance matrices between wells and tie-ins to determine a plurality of connections at step 110, filtering out connections that do not abide by the set of parameters at step 112, prioritizing optimal well scenarios at step 114, and updating the arrays to include the optimal well scenarios at step 116.

The parameters received as input include well locations and tie-in locations. The wells may be any existing wells located within a given area of interest. For example, existing Well-A is connected to existing Well-B which connects to Manifold-X. A future Well-C tie-in point may be evaluated by the method to be either Well-A, Well-B, or Manifold-X. In some embodiments, the total number of nozzles of Manifold-X may also be an input. As per the same example, if the capacity of Manifold-X was to be only one nozzle, then the workflow would not propose connecting future Well-C to Manifold-X as that nozzle is occupied by Well-B. The existing wells may be any existing wells located within a given area of interest. Such an area of interest may be any given radius around one or more hydrocarbon facilities, an oil field, or any arca surrounding a reservoir that may contain features relevant to the planning of hydrocarbon facilities. These locations may be provided in coordinate systems. For example, in an embodiment, the well locations may be provided with x and y coordinates in a two-dimensional space. Additional features of the wells may also be provided in three-dimensional space. Such features may be provided by simulation models. A tie-in may be any point that already is or may become a connection to an existing process. For example, the tie-in locations may include the existing or potential connections between existing wells, future wells, and manifolds. A manifold may be any system of piping or headers that can gather or distribute fluids.

According to another embodiment consistent with the present disclosure, method 100 may further include preparing a surface facilities network as field data at step 118. For example, the surface facilities network may be prepared as a database.

In a further embodiment, the set of parameters may also include said field data, surface facility constraints, user-imposed constraints, reservoir simulation models, surface simulation models, future well locations, or any combination thereof. Field data may include data on existing facilities, facilities designs, existing well locations, tie-in locations, or any combination thereof. Thus, such field data may be prepared in a digestible form, such as a database, and may be used as input for the ensuing method and workflow. Depending on any given constraints, each data point from the surface facility network, such as the wells for example, may allow a specific number of connections to it. These connections may be direct or indirect. A direct connection may be any connection directly from a well to a main manifold, whereas an indirect connection may be two or more wells utilizing the same flowline at any point to reach a main manifold.

Future well locations may also be provided with x and y coordinates, and aforementioned areas of interest may be provided by bounds defined by maximum and minimum x coordinates, and maximum and minimum y coordinates. For example, future well A could be provided by (x,y) coordinates (22, 50) within an area of interest (xₘᵢₙ, xₘₐₓ) of (10, 2500) and (yₘᵢₙ, yₘₐₓ) of (10, 2500). These values may further be extracted from reservoir simulation models. The use of these points and areas of interest as an input into the iterative workflow will allow for a more comprehensive accounting of subsurface uncertainty. Surface facilities constraints may be obtained from a user and/or from the surface simulation models. For example, these constraints could be provided by a user from the field data describing the existing facilities or facilities designs. These could include but are not limited to their locations, their size and shape, their proximity to other facilities or pertinent obstacles within the oil field like wells or manifolds, their structure and layout, their potential interaction or connectivity to future wells or future planned facilities, and what purpose the facility performs or what inventory or machinery it may contain for general oil field purposes. The parameters and constraints may also include, but are not limited to, other data on wells such as type (horizontal or vertical), geometry, length, location, other existing or previously planned wells in the current reservoir of interest or the overlaying shallower reservoirs, geomechanics constraints such as high-risk reservoir areas where high stress may be located as well as the potential for losses, data on drilling constraints such as buildup radius, water handling capacity, ullage constraints, cost of drilling and completion data, and water production and injection attributes.

Multiple reservoir simulation models may be used as part of the input to capture inherited subsurface uncertainty. A reservoir simulation model may be any model which integrates subsurface properties such as well logs, geological properties, fluid properties, etc. For example, a model of a reservoir may be a three-dimensional representation of the geological structure, facies, and petrophysical properties of the reservoir. Multiple reservoir simulation models may be used to estimate the volume and distribution of the hydrocarbons in the reservoir, the connectivity, or the pressure and saturation conditions, and allow for broad capture of the uncertainty inherited from the uncertainty in the subsurface data. Multiple reservoir simulation models as input allows their predictions to be spread enough to cover the range of possible outcomes. The reservoir simulation models may be static or dynamic. A dynamic reservoir simulation model may be any simulation that integrates the changes in the static properties of the reservoir with time. Dynamic models may be used to forecast performance and recovery under different strategies such as placement, injection, and completion.

The extensive aforementioned parameters may then be sorted into a multitude of arrays. For example, the parameters pertaining to the future wells may be sorted into a future well array. These arrays may include their location coordinates, labels, or any other parameters or properties received as input. In further examples, the existing wells may be sorted into one or more existing well arrays, the existing manifolds may be sorted into existing manifold arrays, the existing facilities into existing facilities arrays, and so on amongst relevant parameters received as input. In a prominent example, the locations of such future wells, existing wells, and manifolds may be utilized to calculate various distances. These arrays may exist in readily available forms, such as digitally, virtually, or in analog.

More future well locations may be generated within at least one area of interest. The future wells may also be generated randomly. Generated future well locations may then be sorted into arrays as described above. For example, they may be sorted into the same future wells array as the ones previously provided as input, whether they remain from prior iterations or were organically input at the original start of the process. The areas of interest may be provided by the aforementioned bounds and extracted from the aforementioned simulation models.

Distance matrices may then be constructed by calculating the distances between the wells and tie-ins, namely, a manifold, to determine a plurality of connections. For example, the distance between Well-A and Manifold-1, Well-B to Manifold-1, Well-C to Manifold-1, and so on, may be calculated and organized into matrices. This calculating may be performed across all wells and consist of more than one manifold.

Connections from the plurality of connections that do not abide by the set of parameters may be filtered out of the process, according to at least one embodiment. For example, if there exists a Manifold-A containing 12 nozzles, as well as a total of 12 wells directly connected to Manifold-A, then there are no available nozzles. In such a situation, since Manifold-A is fully occupied, it does not abide by the set of parameters and may be filtered out even if it is a close and feasible point of tie-in. The number of nozzles may also be adjusted by a user, such as increasing the number to 16 nozzles, in order to assess the benefit of planning an expansion of such a manifold. Furthermore, in an embodiment, the workflow may allow such a user input to evaluate the need for expansion by examining the remaining nozzles at the end of workflow iterations. In another example, surface simulation models which consider fluids composition, forecasted rates, and associated pressures, may present a maximum number of wells a flowline may handle. That connection may then not abide by the parameters and be filtered out regardless of its distance if the connection would exceed such a maximum number. For example, Well-A has a pipeline which can only handle three additional wells. If Well-B, Well-C, and Well-D arc all utilizing Well-A as a tie-in point and thus utilizing the same flowline, then a Future-Well-E shall not be connected to Well-A. In another embodiment, an example method of filtering out a connection may be to set the connection to have a dummy infinitely high distance value, such as 10⁹.

With connections that do not abide by the constraints having been filtered out, optimal well scenarios from the remaining connections may then be prioritized. An optimal well scenario may be any scenario that returns the conditions most favorable or suitable for the given well and/or facility location without conflicting with any given constraint placed on the workflow. In an embodiment, with reference to FIG. 1C, prioritizing optimal well scenarios at step 114 may further include attaining closest distances from each well to each tie-in type at step 126, determining a set of avoided distances at step 128, and picking well scenarios wherein the picked scenarios have the highest avoided distance for each tie-in at step 130. In this example, such a scenario would be prioritized as an optimal well scenario, according to some embodiments. Attaining closest distances from each well to each tie-in type may include many such combinations but namely a) closest distances between existing well to closest well, b) closest well to future well to existing manifold, and c) closest well to existing manifold. A set of avoided distances may be determined by comparing all future well to future well to manifold distances against at least one existing well to future well distance, according to at least one embodiment. For example, for all Future-Well-X to Future-Well-Y to Manifold-Z cases, compare the total distance of the X-Y-Z against the Existing-Well-N to Future-Well-M options. These may be considered the avoided distances. Prioritizing the optimal well scenarios may further include prioritizing the future well to future well to manifold distances that are less than the sum of the at least one existing well to future well distance. The distances may include comparisons of all new pipeline distances of an alternative scenario. For example, scenarios like Future-Well-X to Future-Well-Y to Manifold-Z having a distance of 50 meters being less than the sum of the existing well to future well options (Alternative-M and Alternative-Y, representing various options of existing well to future wells) being 150 meters, would be scenarios to be prioritized.

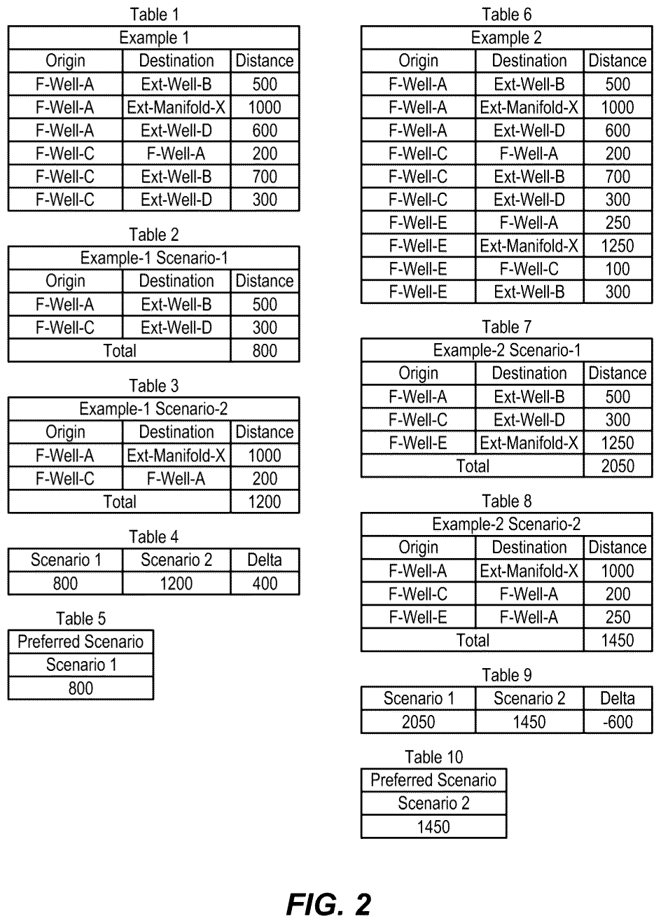

FIG. 2 is a diagram depicting an example of a tabulation of an aforementioned distance comparison scenario and its alternative scenarios, according to at least one embodiment. More specifically, with reference to FIG. 2 and its provided examples for illustration, assume all wells may handle two additional wells. Existing well flowlines (“Ext-Well-X”) are already occupying one additional well and thus can handle one extra. Future wells (“F-Well-X”) are yet to be constructed and thus may handle two additional wells. Table 1 provides for future well origins and their tie-in destinations, as well as the corresponding distances given in m meters, for Example 1. Table 2 provides for Scenario-1, where in the case of F-Well-A to Ext-Well-B (500m), F-Well-C is not allowed to be connected to F-Well-A and thus will go to Ext-Well-D (300m). The total distance in this Scenario-1 would be 800m. Provided by Table 3 is Scenario-2, where in the case of F-Well-A to Ext-Manifold-X (1000m), then F-Well-C may be connected to F-Well-A (200m). The total distance in this Scenario-2 would be 1200m. Comparing the total distances of each scenario, 800m is less than 1200m and thus the first scenario Scenario-1 would be selected due to the 400m of distance avoided. Again, with reference to FIG. 2, Table 6 provides another example for future well origins and their tie-in destinations, as well as the corresponding distances given in m meters, adding a third future well, F-Well-E, for Example 2. Applying the same calculus for two new scenarios provided by Tables 7 and 8, the second scenario with a total distance of 1450m would be selected due to the 600m of distance avoided. Therefore, in this example, even though F-Well-A to Ext-Manifold-X is not optimal for the single-well case provided by Example 1, it would be optimal in the multi-well case provided by Example 2 because it allows for the most distance avoided.

From these prioritized scenarios, the scenarios maintaining the highest avoided distance for each tie-in may then be picked. In another embodiment, if no cases exist where future well to future well to manifold distance is smaller than the at least one existing well to future well distance, then the tie-ins of the smallest distances to existing wells or manifolds will be prioritized. For example, if no cases exist where Future-Well-X to Future-Well-Y to Manifold-Z is smaller than Alternative-M and Alternative-Y, then the tie-ins of the smallest distances to existing wells or manifolds will be prioritized. The optimal well scenarios may then be those that possess the most significant distance avoidance scenarios.

The arrays may then be updated to include the optimal well scenarios. For example, they may be included in an optimal well scenario array. Or, in another example, the optimal well scenario may be included in the existing facilities array, to move forward in future iterations with a new existing facility data point and its potential effects on new future facility or well points. Or, in another example, the individual tie-ins, such as a future well location within the optimal well scenario, may be included to update the future well array if it had not yet been included.

In another embodiment, with reference back to FIG. 1A, method 100 may include reiterating the optimization workflow until the future wells array size becomes zero at step 120, reiterating the optimization workflow until desired results are achieved at step 122, and analyzing the results at step 124. Reiterating may include each step being reiterated any number of times. The future well array becoming zero may include every future well data point of interest to a user or general oil field development team being tested until there are no longer any future well locations of interest to test. This same reiterative logic may also be applied to other arrays containing other data points that a user may be interested in testing the validity of through the constraints. Reiterations may continue until a desired result is achieved. A desired result is any result which may be statistically meaningful to a user of the process. For example, a statistically meaningful result may just be until the future well array is zero. Another statistically meaningful result may include further running the workflow past this point for n-iterations to adequately cover a broad range of uncertainty in the calculations. A statistically meaningful result may further include minimizing or maximizing a statistical significance metric. For example, when a p value representing the probability of obtaining a result at least as extreme, is less than an alpha representing the probability of a result rejecting a null hypothesis. Another example of statistically meaningful application would be the mapping of a normal distribution curve. Results may then be analyzed. Analysis may occur manually or procedurally, by users or programs or computers. Analysis may include determining which results, or more specifically, well or facility scenarios, a user or team of oil field developers would most want to develop in their respective facility planning process. The outcomes of multiple scenarios may explore the uncertainty inherent in such development and allow for more informed decisions on hydrocarbon facility planning and optimization.

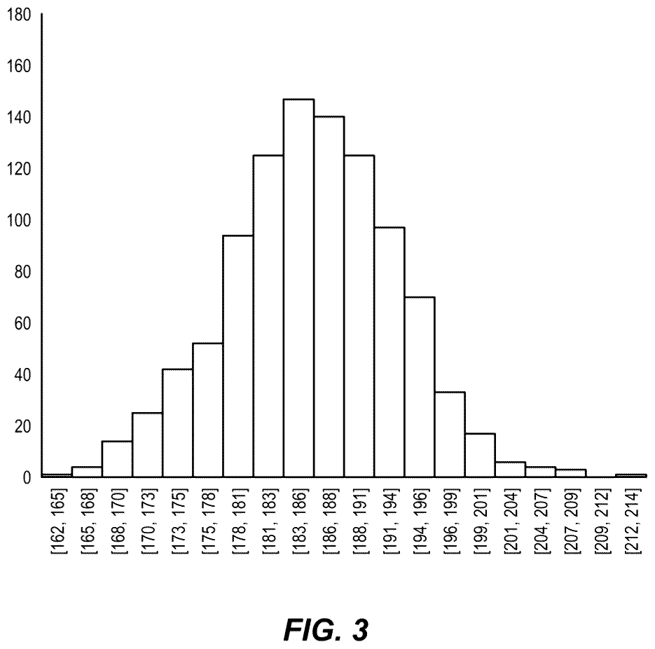

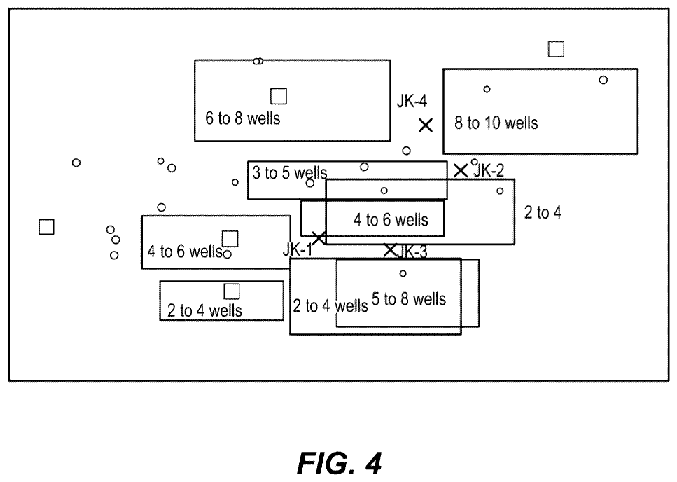

FIG. 3 is a diagram representing an example of a statistical analysis of an arca of total pipeline length utilizing a manifold at a certain location with the number of workflow iterations represented on the y-axes and the distance ranges represented on the x-axis, which may be produced by an embodiment consistent with the present disclosure. FIG. 4 is a diagram representing an example of a map illustration of a solved problem by the workflow. Shapes may represent various assets within an area of interest. For example, various dots may represent existing or future wells. The dots or shapes otherwise may include different coloring or sizing or other visual markers to represent different aspects of the wells. For example, blue dots may be future wells to be drilled in a specific year A while red dots are future wells in a specific year B, according to at least one embodiment. In another example, solid rectangles may represent existing manifolds. With reference to FIG. 4, other rectangles may contain the number of wells anticipated to be drilled within a certain year C while differently denoted rectangles contain the number of wells anticipated to be drilled within a certain year D. X's may represent future manifolds. The workflow may be configured to not connect a future well indicated by year A to a future well indicated by year B, as this will delay the production of well-A by B-A years. This may allow for further statistical results such as when looking for when will manifold X be needed the most. For example, if a result shows the need for a new manifold is required after 12 years, an investment of the construction may be delayed. Any parameter utilized by the workflow may be hidden, for example hiding existing wells to isolate the visual impact of the future-well iteration process. Due to the complexity of reservoir characteristic and the uncertainty in their measurement, each consecutive well drilled may allow for a deeper understanding of the reservoir continuity and potential delineation in the areas of interest with incremental increases in the number of wells. The aforementioned workflow may be run 1000 times, for example, for each future manifold location. The generation of such a visual representation presented in FIG. 4 may be done for each manifold location to analyze and compare. FIGS. 3 and 4 exemplify just two of many ways the result of the disclosed optimization workflow may be presented. Other representations include but are not limited to topographical representations, coordinate-based gridded presentations in two or more dimensions, binary or spectrum-based presentations in response to predetermined thresholds, such as yes or no to honoring an individual or multiple constraints, and numerical data sets in sheets, tables, or graphs. Outcomes may be presented, shared, or distributed amongst any device or media possessing adequate computing or connectivity capabilities, such as but not limited to mobile cellular devices, smart phones, PDAs, personal computers, standalone desktop computers, computer networks, virtual machines, tablets, or the like.

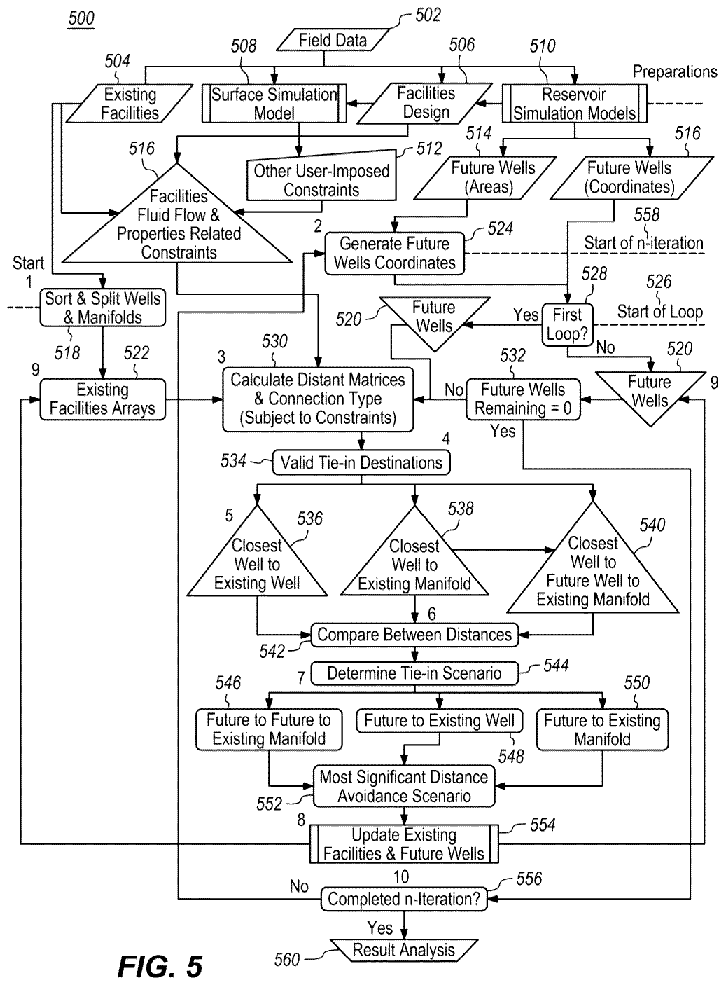

FIG. 5 is a diagram representing an example of a wholistic flow diagram of the method for optimizing the planning of hydrocarbon facilities 500, according to at least one embodiment. Preparations for the workflow may include preparing a surface facility network as field data 502 to be input for the workflow. Field data 502 may include existing facilities 504, facilities designs 506, surface simulation models 508, and reservoir simulation models 510. Field data may also include other user-imposed constraints 512, future wells by areas of interest 514, and future wells by coordinates 516. The future wells by areas of interest 514 and the future wells by coordinates may be provided as user-imposed constraints or by the reservoir simulation models 510. Data on existing facilities 504 may be provided by facilities field flow simulations and other property-related constraints 516. The start of the workflow occurs with sorting 518 the field data 502. For example, existing wells and facilities and future wells and manifolds may be sorted into different arrays, such as future wells arrays 520 and existing facilities arrays 522. More future well coordinates may be generated at 524. The start of the workflow loop 526 begins at determining whether this is the first loop at 528. If yes, then access the future well array 520 and calculate distance matrices and connection types (subject to aforementioned constraints) at 530. If no, then access the future well array 520 and determine if the number of future wells remaining is zero at 532. After distance matrices are calculated 530, tie-in destinations may be checked to determine if they are valid under the constraints at 534. This may include attaining the closest distances from closest wells to existing wells 536, closest wells to existing manifolds 538, and closest wells to future wells to existing manifolds 540, and then comparing between each of those distances at 542. Determining the optimal tie-in scenario 544 may then include attaining future well to future well to existing manifold distances 546, future well to existing well distances 548, future well to existing manifold distances 550, and then determining the most significant avoided distance scenario at 552. The chosen scenario may then be included to update the arrays at 554, such as the existing facility array 522 and the future wells array 520. From the updated future wells array 520, the method returns to the start of the loop 526 to determine if the number of future wells remaining in the array is zero at 532. If no, the process continues forward again as described above with calculating the distance matrices 530. If yes, the entire workflow may be repeated for n-iterations at 556. If the number of n-iterations 556 is not complete, return to the start of the n-iteration 558, where future wells are generated 524. The future wells generated in a first iteration may be different than in iteration 2, 3, 4 . . . n. A different random seed for future well generation 524 may be used in every iteration. If the number of n-iterations 556 is complete, then result analysis 560 may be conducted.

The flow diagram includes the multitude of parameters that may be included as input prior to running the optimization workflow. FIG. 5 further illustrates the reiterative and looping process of the workflow allowing for a smoothing of the uncertainty and bias the results may inherit from the subsurface parameters. The process may also include various logic operators, such as Yes and No to various questions or statuses presented to each iterative step of the workflow, according to some embodiments. For example, with reference to FIG. 5, a block represents the status of whether the future wells remaining in the future wells array is zero at 532. If yes, the flowchart directs to a later step about completed n-iterations 556. If no, the process is returned to the beginning of the looping optimization workflow.

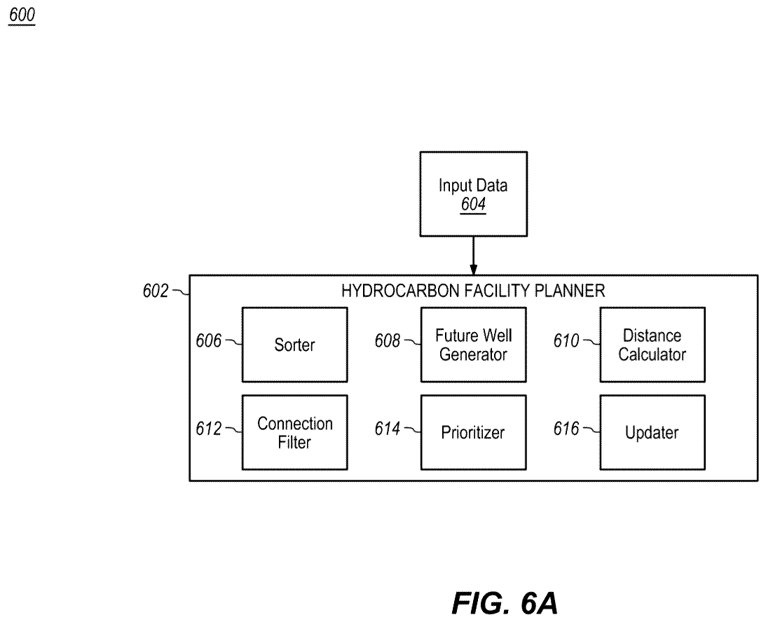

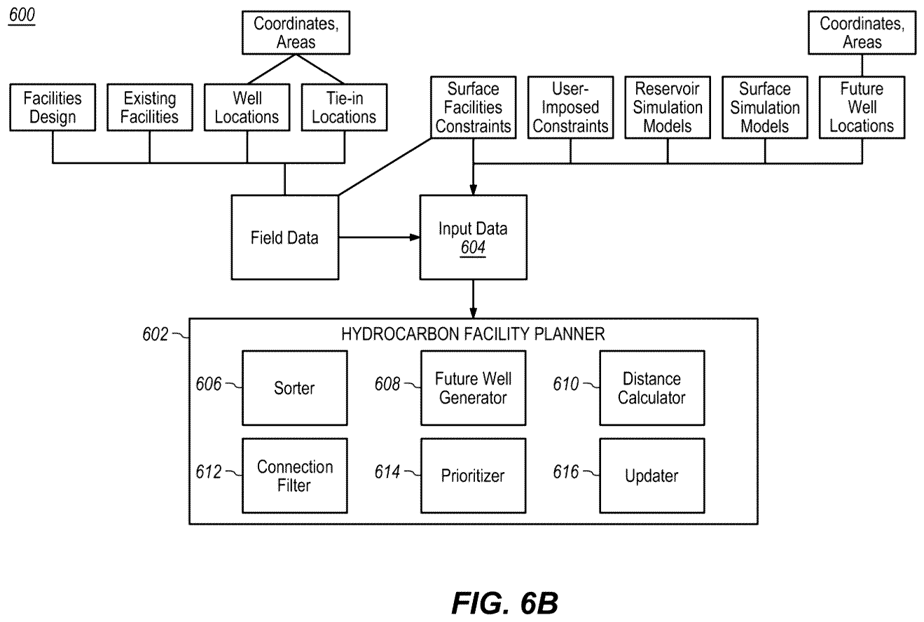

FIGS. 6A and 6B are block diagrams depicting an example of a hydrocarbon facility planning optimization system. System 600 includes a hydrocarbon facility planner 602 configured to receive input data 604, wherein the hydrocarbon facility planner 602 comprises: a sorter 606 operable to sort the input data 604 into different arrays; a future well generator 608 operable to generate future well locations in at least one area of interest; a distance calculator 610 operable to create distance matrices from the sorted input data and future well locations to determine a plurality of connections; a connection filter 612 operable to filter out invalid connections; a prioritizer 614 operable to prioritize optimal well scenarios from the plurality of connections; and an updater 616 operable to update the arrays to include the optimal well scenarios.

With reference to FIG. 6B, input data may include field data, surface facilities constraints, user-imposed constraints, reservoir simulation models, surface simulation models, future well locations, or any combination thereof, according to some embodiments. Field data may include existing facilities, facilities designs, well locations, tie-in locations, or any combination thereof. Future well locations may be provided as points with x coordinates and y coordinates. Areas of interest may be provided by bounds defined by maximum and minimum x coordinates, and maximum and minimum y coordinates.

The system 600 may be operable to execute the method 100 and/or workflow 500 and each of their steps and variations, according to at least one embodiment. Thus, reference can be made to the example of FIGS. 1A-1C and 5 in the example of FIGS. 6A and 6B, as well as the explanations and examples of terms provided above. For example, hydrocarbon facility planner 602 may be operable to execute an optimization workflow upon a set of parameters at step 104 or conduct the looping workflow beginning at sorting 518 or the start of the n-iteration 558. It may also be operable to conduct reiterating the optimization workflow until the future wells array size becomes zero at step 120, reiterating the optimization workflow until desired results are achieved at step 122, and analyzing the results at step 124. Sorter 606 may be operable to conduct sorting the parameters into different arrays including a future wells array at step 106. It may also be operable to conduct the sorting 518 of the field data. Future well generator 608 may be operable to conduct generating future well locations within at least one area of interest at step 108. It may also be operable to generate future well coordinates at 524, according to another embodiment. The distance calculator 610 may be operable to conduct calculating distance matrices between wells and tie-ins to determine a plurality of connections at step 110. It may also be operable to calculate distance matrices 530 and connection types subject to constraints, according to another embodiment. The connection filter 612 may be operable to conduct filtering out connections that do not abide by the set of parameters at step 112. It may also be operable to determine valid tie-in scenarios 534, according to another embodiment. The prioritizer 614 may be operable to conduct prioritizing optimal well scenarios at step 114. The prioritizer 614 may be further operable to conduct attaining closest distances from each well to each tie-in type at step 124, determining a set of avoided distances at step 126, and picking well scenarios wherein the picked scenarios have the highest avoided distance for each tie-in at step 128. It may also be operable to determine an optimal tie-in scenario 544, according to another embodiment. The updater 616 may be operable to conduct updating the arrays to include the optimal well scenarios at step 116. It may also be operable to update the arrays 554, such as the existing facility array 522 and the future wells array 520, according to another embodiment.

While the disclosure has described several exemplary embodiments, it will be understood by those skilled in the art that various changes can be made, and equivalents can be substituted for elements thereof, without departing from the spirit and scope of the invention. In addition, many modifications will be appreciated by those skilled in the art to adapt a particular instrument, situation, or material to embodiments of the disclosure without departing from the essential scope thereof. Therefore, it is intended that the invention not be limited to the particular embodiments disclosed, or to the best mode contemplated for carrying out this invention, but that the invention will include all embodiments falling within the scope of the appended claims. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

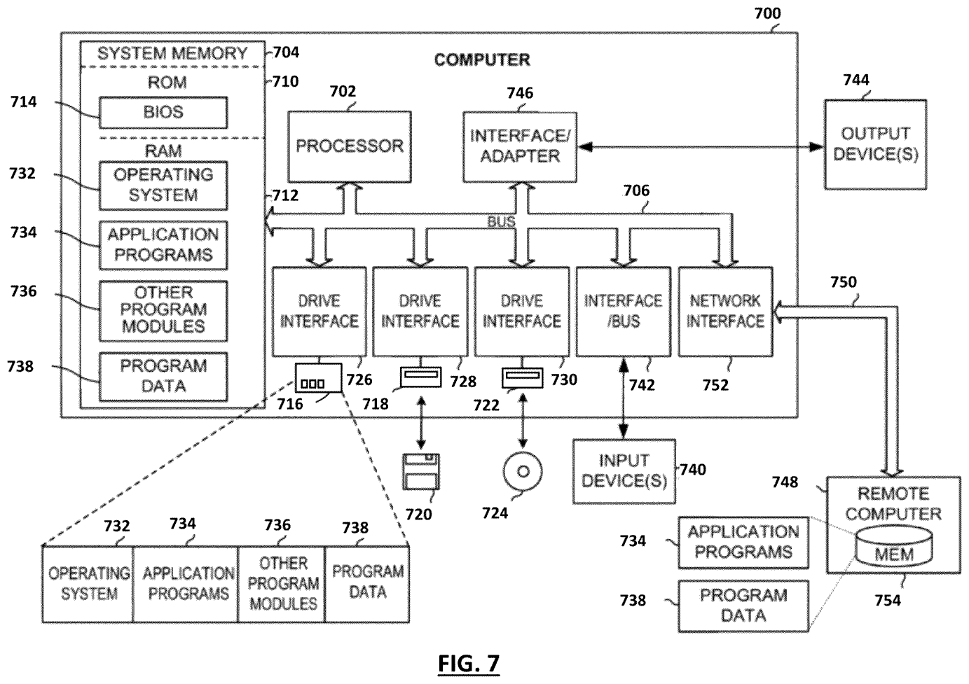

In view of the foregoing structural and functional description, those skilled in the art will appreciate that portions of the embodiments may be embodied as a method, data processing system, or computer program product. Accordingly, these portions of the present embodiments may take the form of an entirely hardware embodiment, an entirely software embodiment, or an embodiment combining software and hardware, such as shown and described with respect to the computer system of FIG. 7. Thus, reference can be made to one or more examples of FIGS. 1-6 in the example of FIG. 7.

In this regard, FIG. 7 illustrates one example of a computer system 700 that can be employed to execute one or more embodiments of the present disclosure. Computer system 700 can be implemented on one or more general purpose networked computer systems, embedded computer systems, routers, switches, server devices, client devices, various intermediate devices/nodes or standalone computer systems. Additionally, computer system 700 can be implemented on various mobile clients such as, for example, a personal digital assistant (PDA), laptop computer, pager, and the like, provided it includes sufficient processing capabilities.

Computer system 700 includes processing unit 702, system memory 704, and system bus 706 that couples various system components, including the system memory 704, to processing unit 702. Dual microprocessors and other multi-processor architectures also can be used as processing unit 702. System bus 706 may be any of several types of bus structure including a memory bus or memory controller, a peripheral bus, and a local bus using any of a variety of bus architectures. System memory 704 includes read only memory (ROM) 710 and random access memory (RAM) 712. A basic input/output system (BIOS) 714 can reside in ROM 712 containing the basic routines that help to transfer information among elements within computer system 700.

Computer system 700 can include a hard disk drive 716, magnetic disk drive 718, e.g., to read from or write to removable disk 720, and an optical disk drive 722, e.g., for reading CD-ROM disk 724 or to read from or write to other optical media. Hard disk drive 716, magnetic disk drive 718, and optical disk drive 722 are connected to system bus 706 by a hard disk drive interface 726, a magnetic disk drive interface 728, and an optical drive interface 730, respectively. The drives and associated computer-readable media provide nonvolatile storage of data, data structures, and computer-executable instructions for computer system 700. Although the description of computer-readable media above refers to a hard disk, a removable magnetic disk and a CD, other types of media that are readable by a computer, such as magnetic cassettes, flash memory cards, digital video disks and the like, in a variety of forms, may also be used in the operating environment; further, any such media may contain computer-executable instructions for implementing one or more parts of embodiments shown and disclosed herein. A number of program modules may be stored in drives and RAM 710, including operating system 732, one or more application programs 734, other program modules 736, and program data 738. In some examples, the application programs 734 can include one or more modules (or block diagrams), or systems, as shown and disclosed herein.

A user may enter commands and information into computer system 700 through one or more input devices 740, such as a pointing device (e.g., a mouse, touch screen), keyboard, microphone, joystick, game pad, scanner, and the like. These and other input devices are often connected to processing unit 702 through a corresponding port interface 742 that is coupled to the system bus, but may be connected by other interfaces, such as a parallel port, serial port, or universal serial bus (USB). One or more output devices 744 (e.g., display, a monitor, printer, projector, or other type of displaying device) is also connected to system bus 706 via interface 746, such as a video adapter.

Computer system 700 may operate in a networked environment using logical connections to one or more remote computers, such as remote computer 748. Remote computer 748 may be a workstation, computer system, router, peer device, or other common network node, and typically includes many or all the elements described relative to computer system 700. The logical connections, schematically indicated at 750, can include a local area network (LAN) and a wide arca network (WAN). When used in a LAN networking environment, computer system 700 can be connected to the local network through a network interface or adapter 752. When used in a WAN networking environment, computer system 700 can include a modem, or can be connected to a communications server on the LAN. The modem, which may be internal or external, can be connected to system bus 706 via an appropriate port interface. In a networked environment, application programs 734 or program data 738 depicted relative to computer system 700, or portions thereof, may be stored in a remote memory storage device 754.

Although this disclosure includes a detailed description on a computing platform and/or computer, implementation of the teachings recited herein are not limited to only such computing platforms. Rather, embodiments of the present disclosure are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models (e.g., software as a service (Saas, platform as a service (PaaS), and/or infrastructure as a service (IaaS)) and at least four deployment models (e.g., private cloud, community cloud, public cloud, and/or hybrid cloud). A cloud computing environment can be service oriented with a focus on statelessness, low coupling, modularity, and semantic interoperability.

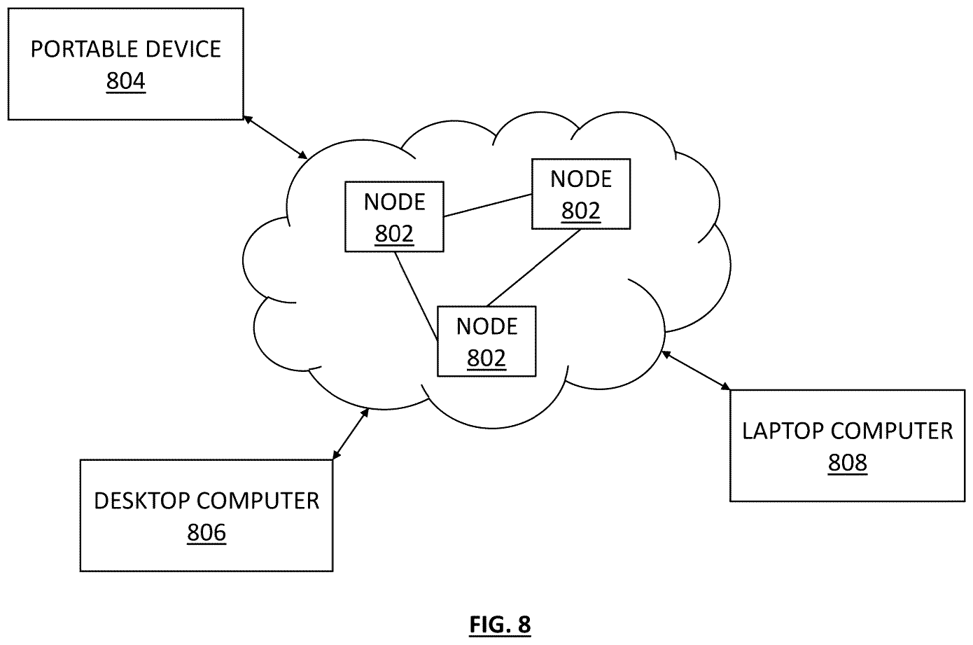

FIG. 8 is an example of a cloud computing environment 800 that can be used for implementing one or more modules and/or systems in accordance with one or more examples, as disclosed herein. Thus, reference can be made to one or more examples of FIGS. 1-7 in the example of FIG. 8. As shown, cloud computing environment 800 can include one or more cloud computing nodes 802 with which local computing devices used by cloud consumers (or users), such as, for example, personal digital assistant (PDA), cellular, or portable device 804, a desktop computer 806, and/or a laptop computer 808, may communicate. The computing nodes 802 can communicate with one another. In some examples, the computing nodes 802 can be grouped (not shown) physically or virtually, in one or more networks, such as Private, Community, Public, or Hybrid clouds, or a combination thereof. This allows the cloud computing environment 800 to offer infrastructure, platforms and/or software as services for which a cloud consumer does not need to maintain resources on a local computing device. The devices 804-808, as shown in FIG. 8, are intended to be illustrative and that computing nodes 802 and cloud computing environment 800 can communicate with any type of computerized device over any type of network and/or network addressable connection (e.g., using a web browser). In some examples, the one or more computing nodes 802 are used for implementing one or more examples disclosed herein relating to root-source identification. Thus, in some examples, the one or more computing nodes can be used to implement modules, platforms, and/or systems, as disclosed herein.

In some examples, the cloud computing environment 800 can provide one or more functional abstraction layers. It is to be understood that the cloud computing environment 800 need not provide all of the one or more functional abstraction layers (and corresponding functions and/or components), as disclosed herein. For example, the cloud computing environment 800 can provide a hardware and software layer that can include hardware and software components. Examples of hardware components include: mainframes; RISC (Reduced Instruction Set Computer) architecture based servers; servers; blade servers; storage devices; and networks and networking components. In some embodiments, software components include network application server software and database software.

In some examples, the cloud computing environment 800 can provide a virtualization layer that provides an abstraction layer from which the following examples of virtual entities may be provided: virtual servers; virtual storage; virtual networks, including virtual private networks; virtual applications and operating systems; and virtual clients. In some examples, the cloud computing environment 800 can provide a management layer that can provide the functions described below. For example, the management layer can provide resource provisioning that can provide dynamic procurement of computing resources and other resources that are utilized to perform tasks within the cloud computing environment. The management layer can also provide metering and pricing to provide cost tracking as resources are utilized within the cloud computing environment 800, and billing or invoicing for consumption of these resources. In one example, these resources may include application software licenses. Security provides identity verification for cloud consumers and tasks, as well as protection for data and other resources. The management layer can also provide a user portal that provides access to the cloud computing environment 800 for consumers and system administrators. The management layer can also provide service level management, which can provide cloud computing resource allocation and management such that required service levels are met. Service Level Agreement (SLA) planning and fulfillment can also be provided to provide pre-arrangement for, and procurement of, cloud computing resources for which a future requirement is anticipated in accordance with an SLA.

In some examples, the cloud computing environment 800 can provide a workload layer that provides examples of functionality for which the cloud computing environment 800 may be utilized. Examples of workloads and functions which may be provided from this layer include: mapping and navigation; software development and lifecycle management; virtual classroom education delivery; data analytics processing; and transaction processing. Various embodiments of the present disclosure can utilize the cloud computing environment 800.

The present disclosure is also directed to the following exemplary embodiments, which can be practiced in any combination thereof:
Embodiment 1: A combination of claims 1-5.
Embodiment 2: A combination of claims 6-13.
Embodiment 3: A combination of claims 14-20.

The present invention may be a system, a method, and/or a computer program product at any possible technical detail level of integration. The computer program product may include a computer readable storage medium (or media) having computer readable program instructions thereon for causing a processor to carry out aspects of the present invention. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware based systems that perform the specified functions or acts or carry out combinations of special purpose hardware and computer instructions.

The terminology used herein is for the purpose of describing particular embodiments only and is not intended to be limiting of the invention. As used herein, for example, the singular forms “a,” “an,” and “the” are intended to include the plural forms as well, unless the context clearly indicates otherwise. It will be further understood that the terms “contains”, “containing”, “includes”, “including,” “comprises”, and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof. In addition, the use of ordinal numbers (e.g., first, second, third, etc.) is for distinction and not counting. For example, the use of “third” does not imply there must be a corresponding “first” or “second.” Also, as used herein, the terms “coupled” or “coupled to” or “connected” or “connected to” or “attached” or “attached to” may indicate establishing either a direct or indirect connection, and is not limited to either unless expressly referenced as such. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The term “based on” means “based at least in part on.” The terms “about” and “approximately” can be used to include any numerical value that can vary without changing the basic function of that value. When used with a range, “about” and “approximately” also disclose the range defined by the absolute values of the two endpoints, e.g. “about 2 to about 4” also discloses the range “from 2 to 4.” Generally, the terms “about” and “approximately” may refer to plus or minus 5-10% of the indicated number.

What has been described above include mere examples of systems, computer program products and computer-implemented methods. It is, of course, not possible to describe every conceivable combination of components, products and/or computer-implemented methods for purposes of describing this disclosure, but one of ordinary skill in the art can recognize that many further combinations and permutations of this disclosure are possible. The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

The invention claimed is:

1. A hydrocarbon facility planning optimization system comprising:
a hydrocarbon facility planner configured to receive input data, wherein the hydrocarbon facility planner comprises:
a sorter operable to sort the input data into different arrays;
a future well generator operable to generate future well locations in at least one area of interest;
a distance calculator operable to create distance matrices from the sorted input data and future well locations to determine a plurality of connections;
a connection filter operable to filter out invalid connections;
a prioritizer operable to prioritize optimal well scenarios from the plurality of connections; and
an updater operable to update the arrays to include the optimal well scenarios.

2. The system of claim 1 wherein the input data further comprises field data, surface facilities constraints, user-imposed constraints, reservoir simulation models, surface simulation models, future well locations, or any combination thereof.

3. The system of claim 2 wherein the field data comprises existing facilities, facilities designs, well locations, tie-in locations, or any combination thereof.

4. The system of claim 1 wherein the future well locations are provided as points with x coordinates and y coordinates.

5. The system of claim 1 wherein the at least one area of interest is provided by bounds defined by maximum x coordinates, minimum x coordinates, maximum y coordinates, and minimum y coordinates.

6. A method for optimizing the planning of hydrocarbon facilities, the method comprising:
receiving a set of parameters as input, including well locations and tie-ins locations;
executing an optimization workflow upon the set of parameters wherein the optimization workflow comprises:
sorting the parameters into different arrays including a future wells array;
generating future well locations within at least one area of interest;
calculating distance matrices between wells and tie-ins to determine a plurality of connections;
filtering out connections that do not abide by the set of parameters;
prioritizing optimal well scenarios; and
updating the arrays to include the optimal well scenarios.

7. The method of claim 6 wherein the set of parameters further comprises field data, surface facilities constraints, user-imposed constraints, reservoir simulation models, surface simulation models, future well locations, or any combination thereof.

8. The method of claim 6 further comprising preparing a surface facilities network as field data.

9. The method of claim 6 further comprising:
reiterating the optimization workflow until the future wells array size becomes zero;
reiterating the optimization workflow until desired results are achieved; and
analyzing the results.

10. The method of claim 6 wherein prioritizing optimal well scenarios further comprises:
attaining closest distances from each well to each tie-in type;
determining a set of avoided distances; and
picking well scenarios wherein the picked scenarios have the highest avoided distance for each tie-in.

11. The method of claim 10 wherein the set of avoided distances are determined by comparing all future well to future well to manifold distances against at least one existing well to future well distance.

12. The method of claim 6 wherein prioritizing the optimal well scenarios further comprises prioritizing the future well to future well to manifold distances that are less than the sum of the at least one existing well to future well distance.

13. The method of claim 12 wherein prioritizing the optimal well scenarios further comprises prioritizing the tie-in of the smallest distances to existing wells or manifolds if no cases exist where future well to future well to manifold distance is smaller than the at least one existing well to future well distance.

14. A computer-readable storage medium containing instructions for optimizing the planning of hydrocarbon facilities, wherein the instructions, when executed by a processor, cause the processor to perform operations comprising:
receiving a set of parameters as input, including well locations and tie-ins locations;
executing an optimization workflow upon the set of parameters wherein the optimization workflow comprises:
sorting the parameters into different arrays including a future wells array;
generating future well locations within at least one area of interest;
calculating distance matrices between wells and tie-ins to determine a plurality of connections;
filtering out connections that do not abide by the set of parameters;
prioritizing optimal well scenarios; and
updating the arrays to include the optimal well scenarios.

15. The computer-readable storage medium of claim 14 wherein the set of parameters further comprises field data, surface facilities constraints, user-imposed constraints, reservoir simulation models, surface simulation models, future well locations, or any combination thereof.

16. The computer-readable storage medium of claim 14, the set of instructions further causing the machine to perform the steps of:
reiterating the optimization workflow until the future wells array size becomes zero;
reiterating the optimization workflow until desired results are achieved; and
analyzing the results.

17. The computer-readable storage medium of claim 14 wherein prioritizing optimal well scenarios further comprises:
attaining closest distances from each well to each tie-in type;
determining a set of avoided distances; and
picking well scenarios wherein the picked scenarios have the highest avoided distance for each tie-in.

18. The computer-readable storage medium of claim 14 wherein the set of avoided distances are determined by comparing all future well to future well to manifold distances against at least one existing well to future well distance.

19. The computer-readable storage medium of claim 14 wherein prioritizing the optimal well scenarios further comprises prioritizing the future well to future well to manifold distances that are less than the sum of the at least one existing well to future well distance.

20. The computer-readable storage medium of claim 14 wherein prioritizing the optimal well scenarios further comprises prioritizing the tie-in of the smallest distances to existing wells or manifolds if no cases exist where future well to future well to manifold distance is smaller than the at least one existing well to future well distance.
